(19) United States
(12) Patent Application Publication
(10) Pub. No.: US 2014/0060905 A1
(43) Pub. Date: Mar. 6, 2014

(54) PRINTED WIRING BOARD AND METHOD FOR MANUFACTURING PRINTED WIRING BOARD

(71) Applicant: IBIDEN CO., LTD., OGAKI (JP)

(72) Inventor: Kazuki KAJIHARA, Ogaki (JP)

(73) Assignee: IBIDEN CO., LTD., OGAKI (JP)

(21) Appl. No.: 14/015,316

(22) Filed: Aug. 30, 2013

(30) Foreign Application Priority Data
Aug. 31, 2012 (JP) 2012-191303

(51) Int. Cl. H05K 1/02; H05K 3/10

(52) U.S. Cl. CPC H05K 1/0298; H05K 3/10
USPC 174/257; 228/165; 174/261

(57) ABSTRACT

A printed wiring board has an interlayer insulation layer, a conductive pattern formed on the interlayer insulation layer, a solder-resist layer formed on the interlayer insulation layer and conductive pattern and having opening exposing a portion of the conductive pattern and a portion of the interlayer insulation layer around the portion of the conductive pattern, a metal layer formed in the opening of the solder-resist layer such that the metal layer is covering the portion of the conductive pattern exposed through the opening of the solder-resist layer, and a bump formed in the opening of the solder-resist layer such that the bump is on the metal layer in the opening of the solder-resist layer. The opening of the solder-resist layer has space formed with side surface of the bump, inner wall of the solder-resist layer and the portion of the interlayer insulation layer in the opening of the solder-resist layer.

### CROSS-REFERENCE TO RELATED APPLICATIONS

The present application is based upon and claims the benefit of priority from Japanese Application No. 2012-191303, filed Aug. 31, 2012, the entire contents of which are incorporated herein by reference.

### BACKGROUND OF THE INVENTION

1. Field of the Invention

The present invention relates to a printed wiring board having a buildup layer formed by alternately laminating interlayer insulation layers and conductive patterns, and to a method for manufacturing such a printed wiring board.

2. Description of Background Art

Japanese Laid-Open Patent Publication No. 2010-103435 describes a structure where space for positioning conductive patterns is enlarged by not forming lands so that the number of conductive patterns is increased. The entire contents of this publication are incorporated herein by reference.

### SUMMARY OF THE INVENTION

According to one aspect of the present invention, a printed wiring board has an interlayer insulation layer, a conductive pattern formed on the interlayer insulation layer, a solder-resist layer formed on the interlayer insulation layer and the conductive pattern and having an opening portion exposing a portion of the conductive pattern and a portion of the interlayer insulation layer around the portion of the conductive pattern, a metal layer formed in the opening portion of the solder-resist layer such that the metal layer is covering the portion of the conductive pattern exposed through the opening portion of the solder-resist layer, and a bump structure formed in the opening portion of the solder-resist layer such that the bump structure is formed on the metal layer in the opening portion of the solder-resist layer. The opening portion of the solder-resist layer has a space formed with a side surface of the bump structure, an inner wall of the solder-resist layer and the portion of the interlayer insulation layer in the opening portion of the solder-resist layer.

According to another aspect of the present invention, a method for manufacturing a printed wiring board includes forming a conductive pattern on an interlayer insulation layer, forming a solder-resist layer on the interlayer insulation layer and the conductive pattern, forming an opening portion in the solder-resist layer such that the opening portion of the solder-resist layer exposes a portion of the conductive pattern and a portion of the interlayer insulation layer around the portion of the conductive pattern, forming a metal layer on the portion of the conductive pattern in the opening portion of the solder-resist layer, and forming a bump structure on the metal layer in the opening portion of the solder-resist layer such that a side surface of the bump structure, an inner wall of the solder-resist layer and the portion of the interlayer insulation layer exposed in the opening portion of the solder-resist layer form a space in the opening portion of the solder-resist layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1(A)-1(C) show steps of manufacturing a printed wiring board according to a first embodiment of the present invention;

FIGS. 2(A)-2(D) show steps of manufacturing a printed wiring board according to the first embodiment;

FIGS. 3(A)-3(C) show steps of manufacturing a printed wiring board according to the first embodiment;

FIGS. 4(A)-4(D) show steps of manufacturing a printed wiring board according to the first embodiment;

FIGS. 5(A)-5(C) show steps of manufacturing a printed wiring board according to the first embodiment;

FIG. 6 is a cross-sectional view of a printed wiring board according to the first embodiment;

FIGS. 7(A)-7(B) show plan views of conductive patterns on the outermost layer;

FIG. 8(A) is a cross-sectional view and FIG. 8(B) is a plan view, showing the positional relationship of a land portion and an opening; FIG. 8(C) is a view illustrating an allowable margin of error between a land portion and an opening;

FIG. 9(A) is an enlarged view of circle (Ca) in FIG. 4(D); FIG. 9(B) is an enlarged view of circle (Cb) in FIG. 5(A); FIG. 9(C) is an enlarged view of circle (Cc) in FIG. 5(B); FIG. 9(D) is an enlarged view of circle (Cd) in FIG. 6;

FIG. 10 is a photograph of a bump taken using a microscope; and

FIGS. 11(A)-11(B) show plan views of conductive patterns of a printed wiring board according to a modified example of the first embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

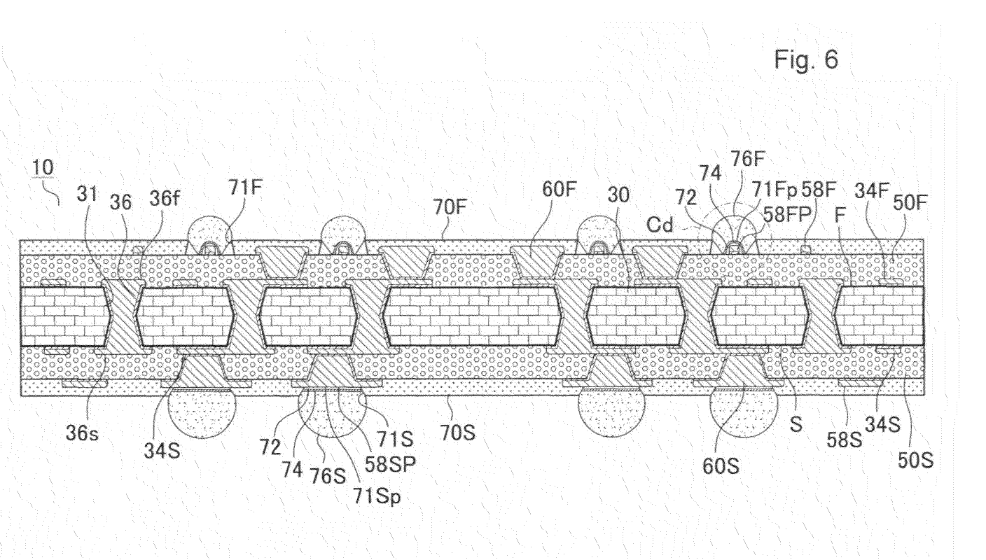

FIG. 6 shows the structure of printed wiring board 10 according to a first embodiment of the present invention. Printed wiring board 10 has core substrate 30 that has first surface (F) (upper surface: the side on which a semiconductor element is to be mounted) and second surface (S) (lower surface: the side on which a motherboard is to be mounted). First conductive patterns (34F) are formed on first surface (F) of core substrate 30 while second conductive patterns (34S) are formed on second surface (S). Through-hole conductors 36 are formed in core substrate 30, and first conductive patterns (34F) and second conductive patterns (34S) are connected by through-hole conductors 36.

First conductor land (360 is formed on the first-surface (F) side end of through-hole conductor 36, while second conductor land (36s) is formed on the second-surface (S) side end. First interlayer insulation layer (50F) is formed to coat first surface (F) of core substrate 30 and first conductive patterns (34F). Conductive patterns (58F) are formed on first interlayer insulation layer (50F), and conductive patterns (58F) and first conductive patterns (34F) are connected by via holes (60F).

Solder-resist layer (70F) is formed to coat first interlayer insulation layer (50F) and conductive patterns (58F). Solder-resist layer (70F) has openings (71F), and solder bumps (76F) are formed in openings (71F).

Second interlayer insulation layer (50S) is formed to coat second surface (S) of core substrate 30 and second conductive patterns (34S). Conductive patterns (58S) are formed on second interlayer insulation layer (505), and conductive patterns (58S) and second conductive patterns (34S) are connected by via holes (60S). Solder-resist layer (70S) is formed to coat second interlayer insulation layer (50S) and conductive patterns (58S). Solder-resist layer (70S) has openings (71S), and solder bumps (76S) are formed in openings (71S).

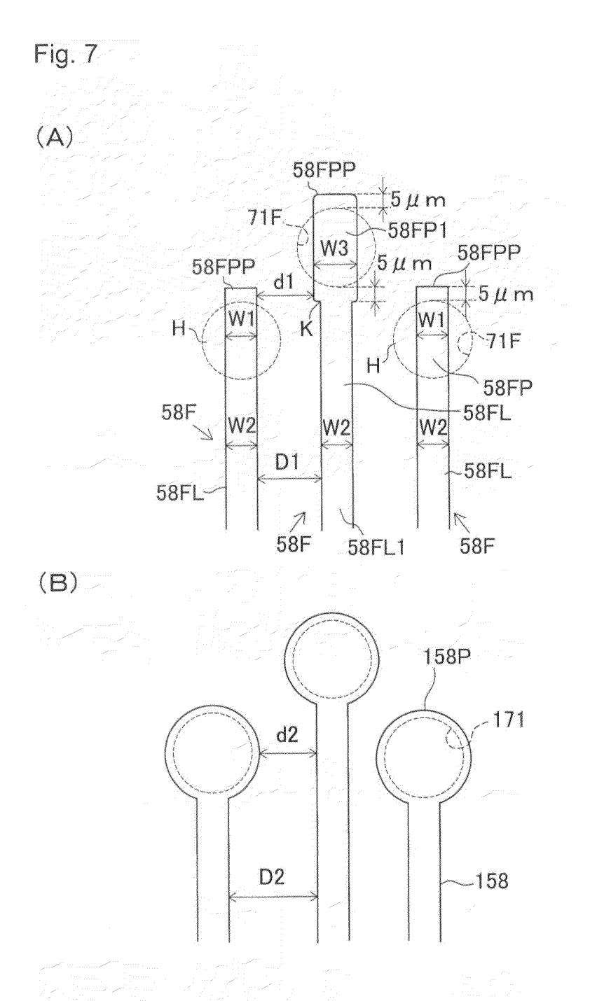

FIG. 7(A) shows a plan view of conductive patterns (58F) formed on first interlayer insulation layer (50F). Chain lines in FIG. 7(A) show openings (71F) of solder-resist layer (70F). In conductive pattern (58F), the portion exposed from opening (71F) of solder-resist layer (70F) works as pad portion (58FP). In pad portion (58FP), solder bump (76F) is formed to be connected with a semiconductor element. Moreover, conductive pattern (58F) has wiring portion (58FL) extending from pad portion (58FP).

In the first embodiment, the diameter of opening (71F) is approximately 50 μm, and width (W1) of pad portion (58FP) is approximately 15 μm. Here, width (W1) of pad portion (58FP) is set to be substantially the same as width (W2) of wiring portion (58FL). Among the pad portions, width (W3) of pad portion (58FP1) is approximately 30 Those pad portions (58FP) are structured to be substantially rectangular when seen in a plan view.

End portion (58FPP) of conductive pattern (58F) is coated by solder-resist layer (70F). Accordingly, adhesion of conductive pattern (58F) to first interlayer insulation layer (50F) is secured. In some of conductive patterns (58F), border portion (K) between pad portion (58FP1) and wiring portion (58FL1) is coated by solder-resist layer (70F). In so setting, border portion (K) is prevented from touching solder bump (76F), thus preventing cracks from originating in border portion (K) and spreading into solder bump (76F).

Furthermore, opening (71F) of solder-resist layer (70F) exposes surface (H) of first interlayer insulation layer (50F) positioned around pad portion (58FP).

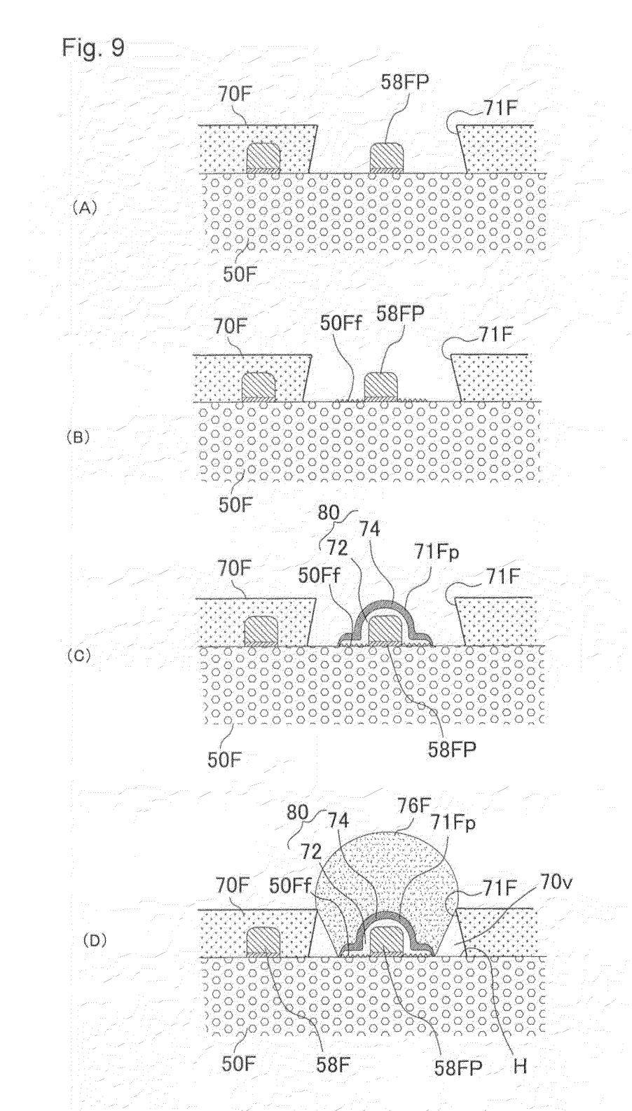

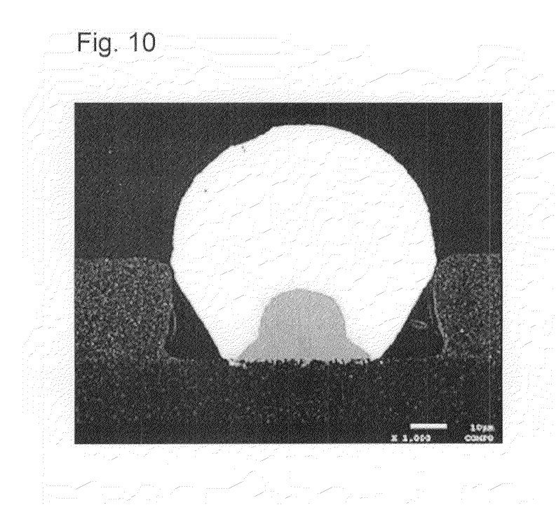

FIG. 9(D) is an enlarged view of a portion shown as circle (Cd) in FIG. 6, which is exposed in opening (71F) of the first-surface (F) side solder-resist layer (70F), and FIG. 10 is a photograph of that portion taken using a microscope. As described above, a portion of interlayer insulation layer (58F) and pad portion (58FP) are exposed in opening (71F) of solder-resist layer (70F). The surface of interlayer insulation layer (50F) exposed in opening (71F) is roughened.

The corners of pad portion (58FP) are formed in substantially an arc shape when seen in a cross-sectional view. Accordingly, if thermal history is added to a printed wiring board, stress exerted on the corners of pad portion (58FP) is mitigated. As a result, it is thought that cracks originating at the corners of pad portion (58FP) and spreading into solder bump (76F) are suppressed.

In addition, as shown in FIG. 9(D), among the portions exposed in opening (71F), metal layer 80 made up of nickel-plated layer 72 and gold-plated layer 74 is provided on pad portion (58FP) and on interlayer insulation layer (50F) positioned near pad portion (58FP). On interlayer insulation layer (50F) exposed in opening (71F), there is a portion with metal layer 80 and another portion without metal layer 80.

The surface of metal layer 80 on pad portion (58FP) is curved in substantially a semicircular shape when seen in a cross-sectional view. That surface of metal layer 80 makes pad portion (71Fp) on which a solder bump is formed. Metal layer 80 is formed to be thinner at the corners of pad portion (58FP) and to be relatively thicker on the upper surface of pad portion (58FP).

Solder bump (76S) is formed on metal layer 80. In opening (71F), space (70v) is formed with the side surface of solder bump (76F), the inner wall of solder-resist layer (70F), and surface (H) of interlayer insulation layer (50F) exposed in opening (71F). Here, the diameter of opening (71F) of solder-resist layer (70F) increases toward the bottom portion (downward). By so setting, compared with an opening whose diameter decreases toward its bottom (downward), it is easier to secure the volume of space (70v), and insulation reliability is enhanced between bump (76S) and the conductive patterns around the bump.

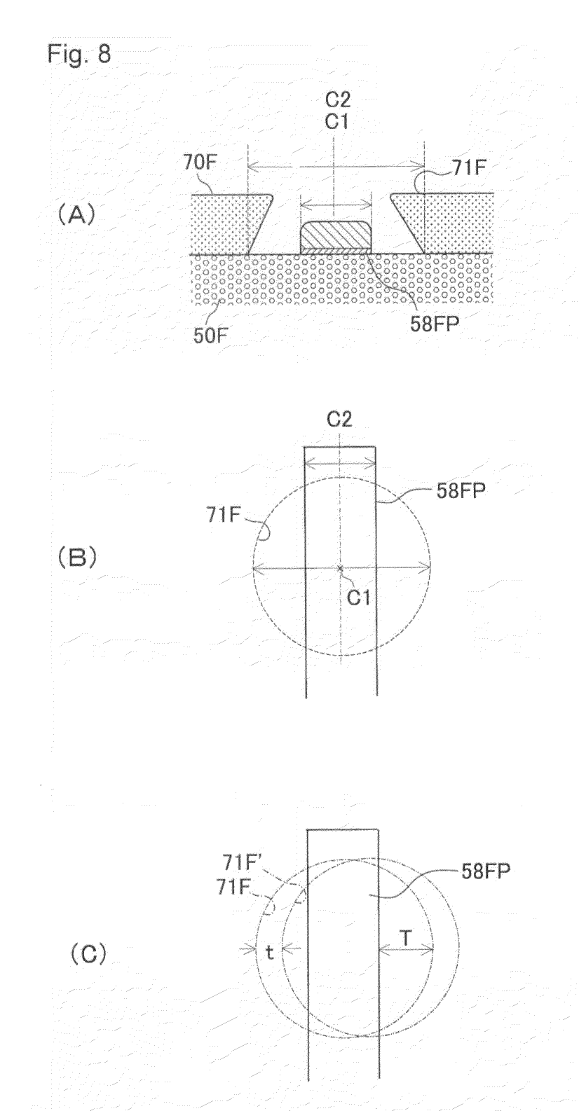

FIG. 8(A) is a cross-sectional view and FIG. 8(B) is a plan view, showing the positional relationship between pad portion (58FP) and opening (71F). Pad (58FP) is aligned in such a way that center (C1) of opening (71F) crosses with virtual line (C2) passing through the center in a width direction and extending along a length direction of pad portion (58FP). Therefore, the left portion of bump (76F) positioned to the left of center (C2) of the pad portion in an axis direction is symmetrical with the right portion of bump (76F) positioned to the right of center (C2). Thus, stress is not concentrated in any local portion, making it easier to secure connection reliability of bump (76F).

FIG. 8(C) shows an allowable margin of error between pad portion (58FP) and opening (71F). Opening (71F) shows an opening without a margin of error. Distance (T) is formed between opening (71F) and a side wall of pad portion (58FP) ((50−15)÷2=17.5 μm). Distance (71F′) is an opening having maximum allowable margin of error (t). In the first embodiment, maximum allowable margin of error (t) is set to be smaller than distance (T).

In a printed wiring board according to the first embodiment, conventional circular pad (158P) shown in FIG. 7(B) is not used. Instead, a portion that works as a pad (pad portion (58FP): width (w1)) and wiring line (58FL) (width (W1)), which is the rest of the pad, are formed to have substantially the same width. Here, to keep insulation distance (d2) (d2≈d1) between circular pad (158P) and conductive pattern 158, space (D2) between conductive patterns is inevitably enlarged (D2>D1).

By contrast, in the first embodiment, pad portion (58FPP) is shaped as a rectangle, and the width is substantially the same as the width of the wiring portion as shown in FIG. 7(A). Accordingly, if distance (d1) between pad portions (58FPP) is the same as (d2) above, space (D1) between conductive patterns is smaller than (D2) above. Namely, according to the first embodiment, the number of conductive patterns per unit area is increased compared with conductive patterns of conventional art. Thus, high-density distribution of conductive patterns is achieved.

Usually, in a printed wiring board to mount a semiconductor element, conductive patterns gradually fan out to have wider pitches from the outermost layer directly under a semiconductor element (the outermost interlayer insulation layer) toward the outermost layer on the motherboard side (the lowermost interlayer insulation layer) so that fine electrodes of the semiconductor element are connected with the electrodes on the motherboard side. Therefore, the density of conductive patterns is the highest on the outermost layer. Accordingly, even higher density is achieved for conductive patterns on the outermost layer, where the highest density of conductive patterns is desired.

In addition, by setting the diameter of opening (71F) of solder-resist layer (70F) to be greater than the width of conductive pattern (58F), even if a margin of error relative to a conductive pattern exists when opening (71F) is formed, it is easier to expose conductive pattern (58F) (pad portion), making it easier to secure the connection of solder bump (76F) to conductive pattern (58F) (pad portion). As a result, excellent connection reliability between a bump and a conductive pattern is achieved.

Moreover, in opening (71F) of solder-resist layer (70F), space (70v) is formed with the side surface of solder bump (76F), the inner wall of solder-resist layer (70F), and surface (H) of interlayer insulation layer (50F) exposed in opening (71F). Accordingly, as shown in FIG. 9(D), the distance between solder bump (76S) and its adjacent conductive pattern (58FN) is increased because of space (70v). As a result, insulation reliability between solder bump (76F) and its surrounding conductive patterns (58FN) is secured.

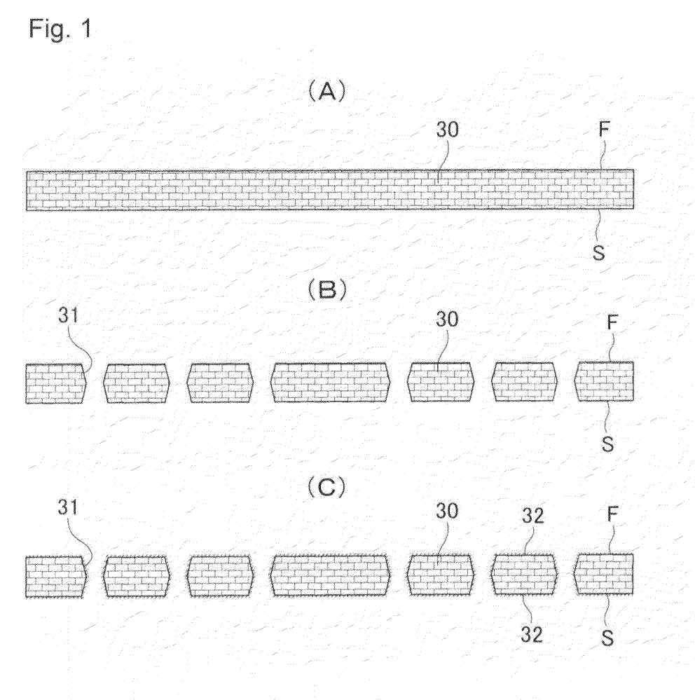

FIG. 1-FIG. 6 show a method for manufacturing printed wiring board 10 shown in FIG. 6.

(1) A starting material is 0.2 mm-thick insulative substrate 30 made by impregnating a core material such as glass cloth with glass epoxy resin or BT (bismaleimide triazine) resin (FIG. 1(A)). Penetrating holes 31 for through-hole conductors are formed by irradiating a laser, for example, from the upper-surface (first surface (F)) side and lower-surface (second surface (S)) side (FIG. 1(B)).

(2) A palladium catalyst (made by Atotech) is applied on the upper surface of insulative substrate 30, and electroless copper plating is performed. Accordingly, 0.6 μm-thick electroless copper-plated film (seed layer) 32 is formed on the upper surface of the substrate and on the side walls of through-hole penetrating holes 31 (FIG. 1(C)).

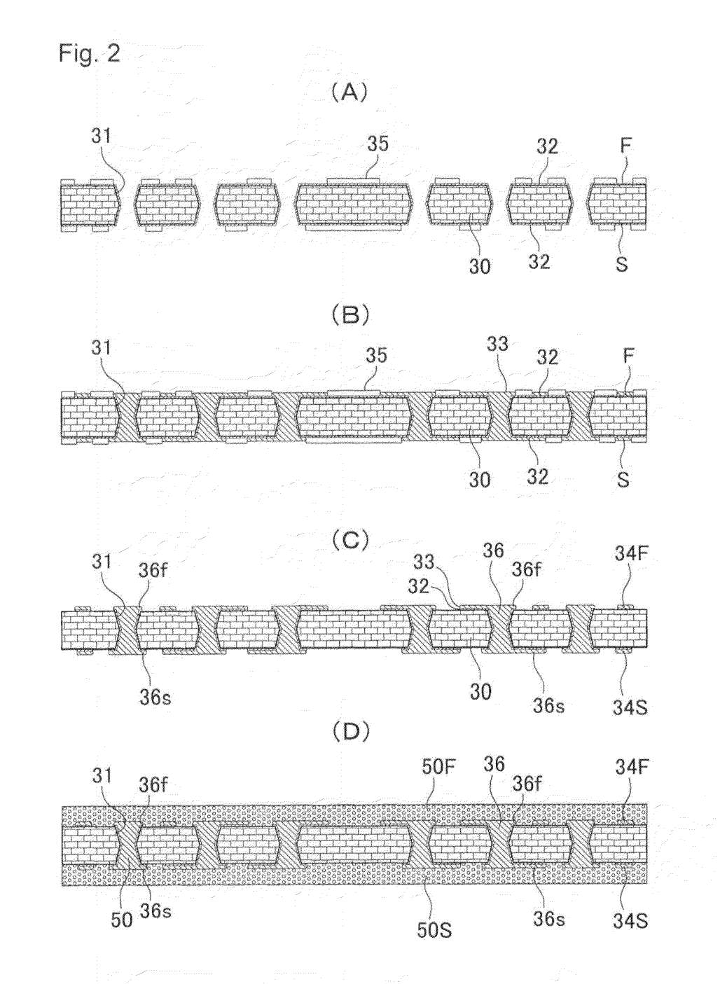

(3) Next, a commercially available dry film is laminated on both surfaces of insulative substrate 30, exposed to light and developed. Accordingly, plating resists 35 are formed (FIG. 2(A)).

(4) Electrolytic plating is performed to form electrolytic copper-plated film 33 in penetrating holes 31 and on portions of substrate 30 without plating resist 35 (FIG. 2(B)).

(5) Then, after plating resists 35 are removed using an amine solution, electroless plated film 32 where plating resists were positioned is dissolved and removed by an etching solution mainly containing copper (II) chloride to form first conductive patterns (34F) and second conductive patterns (34S) including first conductive lands (36f) and second conductive lands (36s) (FIG. 2(C)).

(6) On the upper surface (first surface) and second surface (lower surface) of substrate 30, resin interlayer insulation film (brand name ABF-45SH, made by Ajinomoto), which does not contain reinforcing material and has a slightly larger size than the substrate, is placed, preliminarily pressed, cut to size and further laminated using a vacuum laminator. Accordingly, first interlayer insulation layer (50F) and second interlayer insulation layer (50S) are formed (FIG. 2(D)).

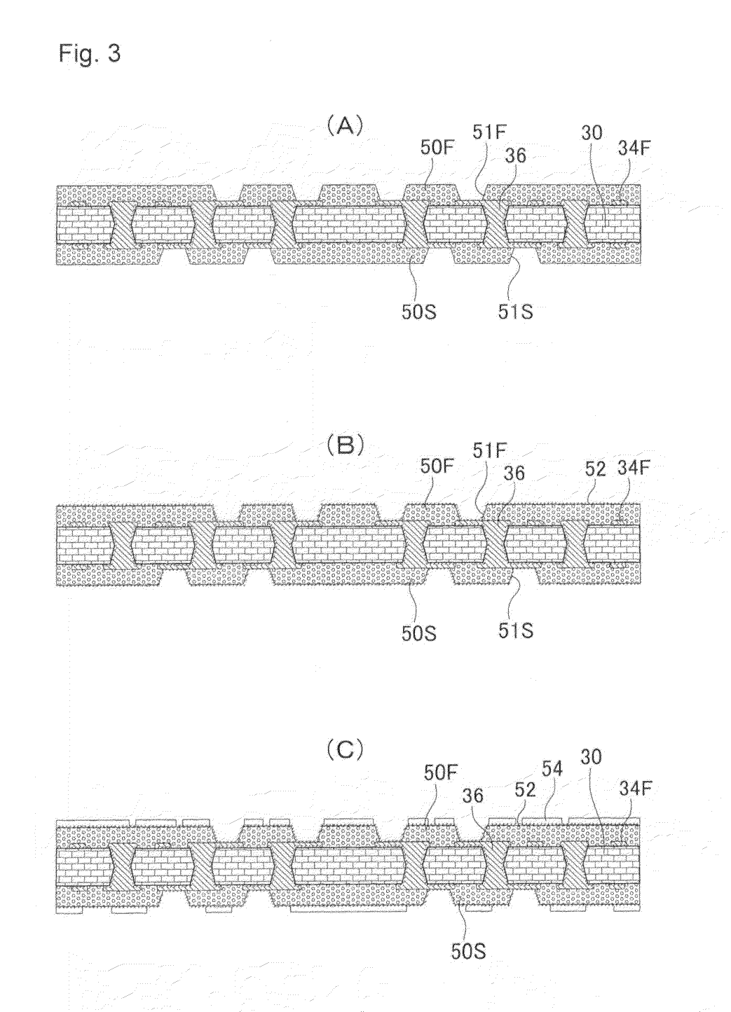

(7) Next, using a CO2 gas laser, via-hole openings (51F, 51S) are formed in interlayer insulation layers (50F, 50S) (FIG. 3(A)).

(8) After via-hole openings (51F, 51S) are formed, the substrate is immersed for 10 minutes in an 80° C. solution containing 60 g/L permanganic acid to remove particles on the upper surfaces of interlayer insulation layers (50F, 50S). Accordingly upper surfaces of interlayer insulation layers (50F, 50S) including inner walls of via-hole openings 51 are roughened (not shown).

(9) Next, after the above treatment the substrate is immersed in a neutralizer (made by Shipley Company LLC) and washed with water. Moreover, a palladium catalyst is applied on the roughened upper surfaces of the substrate so that catalyst nuclei are attached to the upper surfaces of interlayer insulation layers and on the inner-wall surfaces of via-hole openings.

(10) Next, the substrate with the attached catalyst is immersed in an electroless copper plating solution (Thru-cup PEA) made by C. UYEMURA & CO LTD. so that electroless copper-plated film with a thickness of 0.3 μm˜3.0 μm is formed on the entire roughened surface. Accordingly, a substrate is obtained, having an electroless copper-plated film 52 on upper surfaces of first interlayer insulation layer (50F) and second interlayer insulation layer (50S) including the inner walls of via-hole openings (51F, 51S) (FIG. 3(B)).

(11) A commercially available photosensitive dry film is laminated on the substrate having electroless copper-plated film 52, masking film is placed, and exposure/development treatment is performed to form plating resists 54 (FIG. 3(C)).

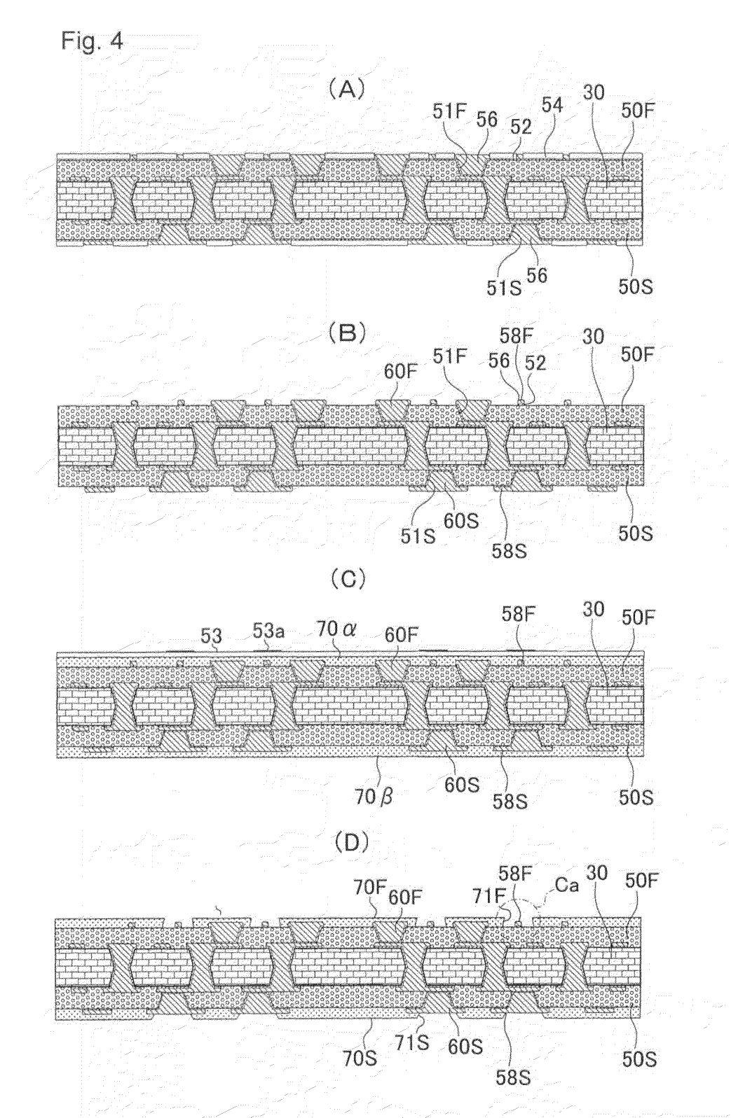

(12) The substrate is washed with 50° C. water for degreasing, washed again, and further cleansed by sulfuric acid. Then, electrolytic plating is performed to form 15 μm-thick electrolytic copper-plated film 56 on portions where plating resists 54 are not formed (FIG. 4(A)).

(13) Then, after plating resists 54 are removed by 5% KOH, the electroless plated film beneath the plating resists are etched away by a mixed solution of sulfuric acid and hydrogen peroxide. Accordingly, conductive patterns (58F, 58S) and via holes (60F, 60S) are formed (FIG. 4(B)). Next, the upper surfaces of conductive patterns (58F, 58S) and via holes (60F, 60S) are roughened.

After that, the palladium catalyst remaining on interlayer insulation layer (50F) is removed. As for a method for removing palladium catalyst, treatments using liquid, CO₂ laser, plasma or the like may be employed. Among those, CO₂ laser treatment is preferred, considering the ease of removal. Moreover, when the palladium catalyst is removed, it is preferred to leave the palladium catalyst near pad portions (58FP).

(14) Next, after a commercially available solder-resist composition is applied on both surfaces of a multilayer wiring board to have a thickness of 20 μm and dried, a 5 mm-thick photomask with opening patterns for a solder-resist layer is adhered to each of the solder-resist layers, exposed to UV rays and developed using a DMTG solution. Accordingly, openings (71F) with a smaller diameter are formed on the upper-surface side, and openings (71S) with a larger diameter are formed on the lower-surface side (FIG. 4(C)). A portion of conductive pattern (58F) exposed in opening (71F) makes pad portion (58FP). Moreover, the solder-resist layers are thermally cured to form 15˜25-μm thick solder-resist layers (70F, 70S) having openings.

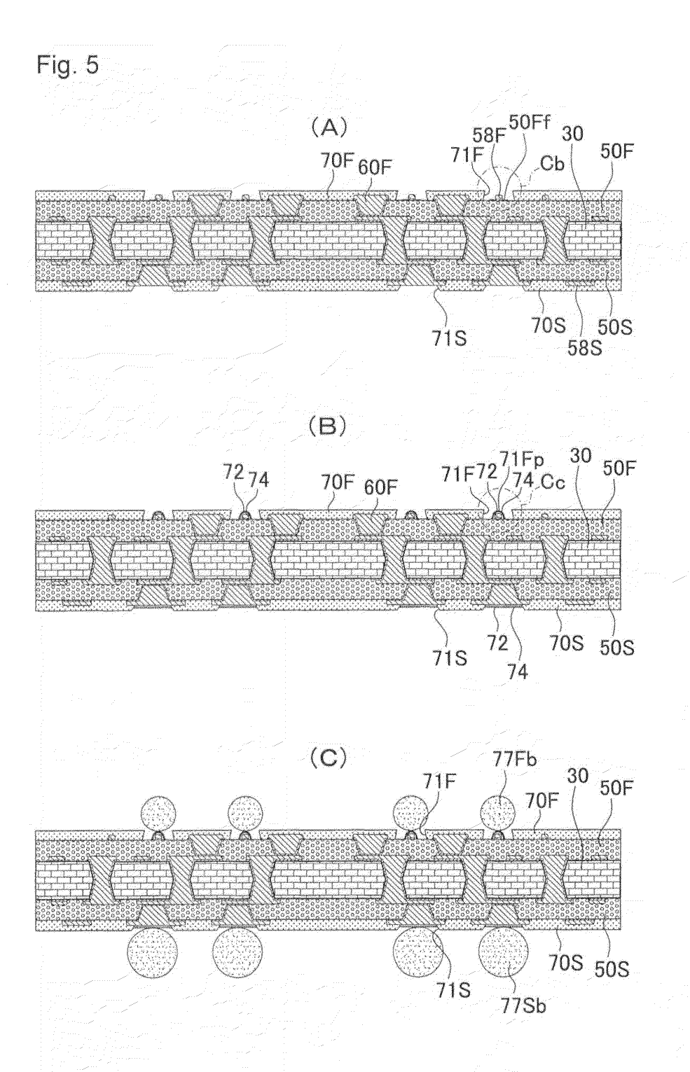

(15) Oxygen plasma treatment is conducted in openings (70F) of solder-resist layers (71F) to roughen the surfaces of interlayer insulation layer (50F) exposed in the openings (FIG. 5(A)). FIG. 9(A) shows an enlarged view of circle (Ca) shown in FIG. 5(A).

(16) Next, the substrate with solder-resist layers (70F, 70S) is immersed in an electroless nickel-plating solution to form 5 μm-thick nickel-plated layer 72 in openings (71F, 71S). Furthermore, the substrate is immersed in an electroless gold plating solution to form 0.03 μm-thick gold-plated layer 74 on nickel-plated layer 72 (FIG. 5(B)). At that time, since the palladium catalyst remains on the entire portion exposed in opening (71F), the metal layer made of nickel-plated layer 72 and gold-plated layer 74 is formed on the entire portion exposed in opening (71F).

FIG. 9(B) is an enlarged view of circle (Cc) shown in FIG. 5(B). As described above, the palladium catalyst remains in portions near pad portion (58FP). Thus, metal layer 80 is also formed on interlayer insulation layer (50F) near pad portion (58FP) in opening (71F). Accordingly, compared with an example where metal layer 80 is formed only on pad portion (58FP), the volume of a solder bump is increased in the present embodiment, thus the stress while mounting a semiconductor element is effectively mitigated.

Instead of nickel-gold layers, nickel-palladium-gold triple layers, or a single layer of a noble metal (such as gold, silver, palladium, platinum or the like) may also be formed as the metal layer. As described above, the surface of metal layer 80 on pad portion (58FP) is curved in a semicircular shape when seen in a cross-sectional view. Also, the surface of gold-plated layer 74 is curved, becoming thinner at the tip of pad portion (58FP).

(17) After flux (not shown) is applied in openings (71F, 71S), solder balls (77Fb) are loaded in opening (71F) of upper-surface side solder-resist layer (70F), and solder balls (77Sb) are loaded in openings (71S) of lower-surface side solder-resist layer (70S) (FIG. 5(C)). Next, a reflow is conducted to form solder bumps (76F) on the upper-surface side and solder bumps (76S) on the lower-surface side (FIG. 6). In opening (71F), space (70v) is formed with the side surface of solder bump (76F), the inner wall of solder-resist layer (70F), and surface (H) of interlayer insulation layer (50F) exposed in opening (71F).

A semiconductor element is mounted on printed wiring board 10, and a reflow is conducted so that pad portions of the printed wiring board and electrodes of the semiconductor element are connected through solder bumps (76F) (not shown).

In the method for manufacturing a printed wiring board according to the first embodiment, after solder-resist layer (70F) is formed, the surface of interlayer insulation layer (50F) exposed in opening (71F) is roughened. Then, a metal layer is formed on the roughened surface of the interlayer insulation layer, and a bump is formed on the metal layer. Thus, the connection reliability of a bump to the portion (interlayer insulation layer) exposed in opening (71F) is enhanced.

### First Modified Example of the First Embodiment

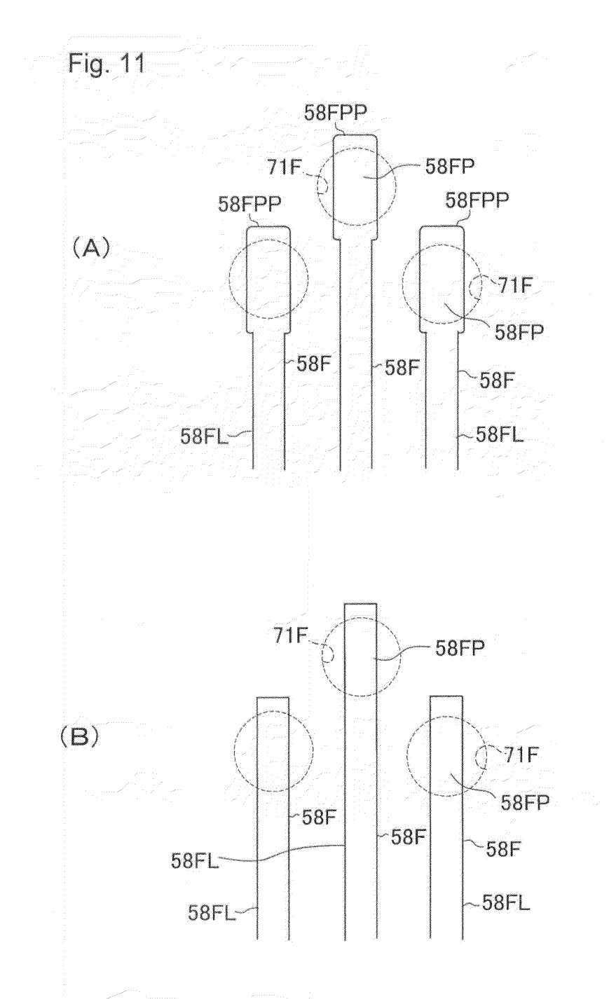

FIG. 11(A) is a plan view of conductive patterns (58F) of a printed wiring board according to a first modified example of the first embodiment. Pad portion (58FP) is formed on rectangular pad portion (58FPP) in the first modified example of the first embodiment. Since the width of pad portion (58FP) is wider in the first modified example of the first embodiment, connection reliability is enhanced between pad portion (58FP) and a bump.

### Second Modified Example of the First Embodiment

FIG. 11(B) is a plan view of conductive patterns (58F) of a printed wiring board according to a second modified example of the first embodiment. Rectangular pad portions are not formed in the second modified example of the first embodiment. The density of conductive patterns is further enhanced in the second modified example of the first embodiment.

A printed wiring board according to an aspect of the present invention has an interlayer insulation layer, a conductive pattern formed on the interlayer insulation layer, and a solder-resist layer having an opening to expose at least part of the conductive pattern and the interlayer insulation layer positioned around the conductive pattern. In such a printed wiring board, a metal layer is formed on the conductive pattern exposed in the opening, a bump is formed on the metal layer, and space is formed with the side surface of the bump, the inner wall of the solder-resist layer and the surface of the interlayer insulation layer exposed in the opening.

In a printed wiring board according to an embodiment of the present invention, at least a portion of a conductive pattern and the interlayer insulation layer positioned around the conductive pattern are exposed in an opening of the solder-resist layer. Namely, the width of a conductive pattern (pad) is set smaller than the diameter of an opening of the solder-resist layer. Thus, compared with an example where the diameter of an opening of the solder-resist layer is set smaller than the diameter of a pad, the region that pads occupy is smaller, allowing high-density distribution of conductive patterns. Moreover, in an opening of the solder-resist layer, space is formed with the side surface of a bump, the inner wall of the solder-resist layer and the surface of the interlayer insulation layer exposed in the opening. Accordingly, the distance between a bump and the conductive patterns near the bump is increased because of such space. As a result, insulation reliability is secured between a bump and the conductive patterns around the bump.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
an interlayer insulation layer;
a conductive pattern formed on the interlayer insulation layer;
a solder-resist layer formed on the interlayer insulation layer and the conductive pattern and having an opening portion exposing a portion of the conductive pattern and a portion of the interlayer insulation layer around the portion of the conductive pattern;
a metal layer formed in the opening portion of the solder-resist layer such that the metal layer is covering the portion of the conductive pattern exposed through the opening portion of the solder-resist layer; and
a bump structure formed in the opening portion of the solder-resist layer such that the bump structure is formed on the metal layer in the opening portion of the solder-resist layer,
wherein the opening portion of the solder-resist layer has a space formed with a side surface of the bump structure, an inner wall of the solder-resist layer and the portion of the interlayer insulation layer in the opening portion of the solder-resist layer.

2. The printed wiring board according to claim 1, wherein the metal layer has a portion formed along the portion of the conductive pattern such that the portion of the metal layer is formed on a surface of the portion of the interlayer insulation layer exposed in the opening portion of the solder-resist layer.

3. The printed wiring board according to claim 1, wherein the metal layer has a portion formed on the portion the conductive pattern such that the portion of the metal layer on the portion of the conductive pattern has a curved surface.

4. The printed wiring board according to claim 1, wherein the conductive pattern has a pad portion on which the bump structure is formed, and the pad portion of the conductive pattern has substantially a rectangular shape.

5. The printed wiring board according to claim 4, wherein the pad portion of the conductive pattern has a plurality of corners having substantially an arc shape in a cross-section.

6. The printed wiring board according to claim 4, wherein the opening portion of the solder-resist layer has the center positioned in the center of the pad portion of the conductive pattern in an axis direction of the pad portion of the conductive pattern.

7. The printed wiring board according to claim 1, wherein the opening portion of the solder-resist layer has a diameter which increases toward the portion of the interlayer insulation layer exposed through the opening portion of the solder-resist layer.

8. The printed wiring board according to claim 1, wherein the metal layer is formed of a single layer made of a metal selected from the group consisting of tin, gold, silver, palladium and platinum.

9. The printed wiring board according to claim 1, wherein the metal layer is formed of a single layer.

10. The printed wiring board according to claim 1, wherein the conductive pattern has an electroless plated film portion and an electrolytic plated film portion formed on the electroless plated film portion.

11. The printed wiring board according to claim 1, wherein the metal layer is formed of a plurality of metal layers.

12. The printed wiring board according to claim 1, wherein the metal layer is formed of a plurality of metal layers comprising a nickel-plated layer and a gold-pated layer formed on the nickel-plated layer.

13. The printed wiring board according to claim 1, wherein the conductive pattern has a pad portion on which the bump structure is formed and a wiring portion extending from the pad portion, the pad portion of the conductive pattern has substantially a rectangle shape, and the wiring portion of the conductive pattern has a width which is substantially equal to a width of the pad portion of the conductive pattern.

14. A method for manufacturing a printed wiring board, comprising:
forming a conductive pattern on an interlayer insulation layer;
forming a solder-resist layer on the interlayer insulation layer and the conductive pattern;
forming an opening portion in the solder-resist layer such that the opening portion of the solder-resist layer exposes a portion of the conductive pattern and a portion of the interlayer insulation layer around the portion of the conductive pattern;
forming a metal layer on the portion of the conductive pattern in the opening portion of the solder-resist layer; and
forming a bump structure on the metal layer in the opening portion of the solder-resist layer such that a side surface of the bump structure, an inner wall of the solder-resist layer and the portion of the interlayer insulation layer exposed in the opening portion of the solder-resist layer form a space in the opening portion of the solder-resist layer.

15. The method for manufacturing a printed wiring board according to claim 14, wherein the forming of the conductive pattern comprises applying a catalyst on the interlayer insulation layer, forming an electroless plated film on the interlayer insulation layer, forming a plating resist having a pattern on the electroless plated film, forming an electrolytic plated film on a portion of the electroless plated film exposed through the pattern of the plating resist, and removing the plating resist and a portion of the electroless plated film underneath the plating resist such that the conductive pattern comprising the electrolytic plated film and the portion of the electroless plated film underneath the electrolytic plated film is formed on the interlayer insulation layer.

16. The method for manufacturing a printed wiring board according to claim 14, further comprising removing the catalyst from the interlayer insulation layer before the forming of the solder-resist layer.

17. The method for manufacturing a printed wiring board according to claim 16, wherein the removing of the catalyst includes irradiating laser such that the catalyst is removed from the interlayer insulation layer.

18. The method for manufacturing a printed wiring board according to claim 15, further comprising removing the catalyst from the interlayer insulation layer before the forming of the solder-resist layer.

19. The method for manufacturing a printed wiring board according to claim 18, wherein the removing of the catalyst includes irradiating laser such that the catalyst is removed from the interlayer insulation layer.

20. The method for manufacturing a printed wiring board according to claim 14, wherein the forming of the opening comprises forming the opening portion in the solder-resist layer such that the opening portion has a diameter which increases toward the portion of the interlayer insulation layer exposed through the opening portion of the solder-resist layer.
